(19) United States
(12) Patent Application Publication
(10) Pub. No.: US 2012/0000416 A1
(43) Pub. Date: Jan. 5, 2012

(54) SINGLE CRYSTAL COOLING APPARATUS AND SINGLE CRYSTAL GROWER INCLUDING THE SAME

(76) Inventors: Hak-Eui Wang, Gumi-si (KR); Gwang-Ha Na, Gumi-si (KR)

(21) Appl. No.: 13/039,275

(22) Filed: Mar. 2, 2011

(30) Foreign Application Priority Data
Mar. 2, 2010 (KR) 10-2010-0018534

(51) Int. Cl. C30B 15/20; F28F 7/00

(52) U.S. Cl. 117/217; 165/185

(57) ABSTRACT

Provided are a single crystal cooling apparatus and a single crystal grower including the same. The single crystal cooling apparatus includes an upper flange having a circular shape and a lower flange extending downward from the upper flange, the lower flange having a diameter less than that of the upper flange.

### CROSS-REFERENCE TO RELATED APPLICATION

This application claims under 35 U.S.C. §119 to Korean Patent Application No. 10-2010-0018534, filed Mar. 02, 2010, which is hereby incorporated by reference in its entirety.

### BACKGROUND OF THE INVENTION

1. Field of the Invention

Embodiments relate to a single crystal cooling apparatus and a single crystal grower including the same.

2. Description of the Related Art

To manufacture a wafer, single crystal silicon should be grown in an ingot form.

A representative method for growing a silicon single crystal ingot is a czochralsk (CZ) method in which a single seed crystal is immersed in liquid silicon, and then the single seed crystal slowly pulls up to grow crystals.

According to a related art, in the growth of the single crystal ingot, a cooling apparatus is disposed above an ingot to absorb heat above the ingot, thereby increasing a growth rate.

However, the cooling apparatus should be disposed maximally close to a melting solution to improve cooling performance. In the cooling apparatus according to the related art, it is impossible to increase the ingot growth rate above a predetermined level because it is difficult to locate the cooling apparatus at a position maximally close to the melt solution so as to detect an ingot diameter through a diameter detection sensor.

### SUMMARY OF THE INVENTION

Embodiments provide a single crystal cooling apparatus, which is disposed maximally close to a surface of a melt solution surface to improve an ingot growth rate, and a single crystal grower including the same.

In one embodiment, a single crystal cooling apparatus includes: an upper flange having a circular shape; and a lower flange extending downward from the upper flange, the lower flange having a diameter less than that of the upper flange.

In another embodiment, a single crystal grower includes: a first chamber including a crucible; a second chamber on the first chamber; and a single crystal cooling apparatus in the first chamber.

The details of one or more embodiments are set forth in the accompanying drawings and the description below. Other features will be apparent from the description and drawings, and from the claims.

### BRIEF DESCRIPTION OF THE DRAWINGS

FIG. 1 is a view illustrating an example of a single crystal grower according to an embodiment.

FIG. 2 is a plan view of a single crystal cooling apparatus according to an embodiment.

FIG. 3 is a plan view of a single crystal cooling apparatus according to another embodiment.

FIG. 4 is a sectional view of a single crystal cooling apparatus according to an embodiment.

FIG. 5 is a sectional view of a single crystal cooling apparatus according to another embodiment.

FIG. 6 is a graph illustrating a coolant temperature variation when a single crystal cooling apparatus is applied according to an embodiment.

### DETAILED DESCRIPTION OF THE EMBODIMENTS

In the descriptions of embodiments, it will be understood that when a wafer, a device, a chuck, a member, a part, a region, or a surface is referred to as being ‘on’ or ‘under’ another wafer, device, chuck, member, part, region, or surface, it can be directly on another wafer, device, chuck, member, part, region, or surface, or intervening elements may also be present. Therefore, meaning thereof should be judged according to the spirit of the present disclosure. In the drawings, the size of each element is exaggerated for convenience in description and clarity. Also, the size of each element does not entirely reflect an actual size.

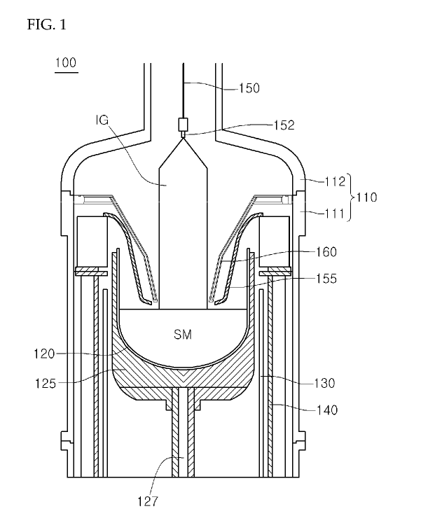

FIG. 1 is a view illustrating an example of a single crystal grower according to an embodiment.

A single crystal grower 100 according to an embodiment may include a chamber 110, a crucible 120, a heater 130, a pulling unit 150, and a cooling apparatus 160.

For example, the single crystal grower 100 according to an embodiment may include the chamber 110, the crucible 120 disposed inside the chamber 110 to receive a silicon solution, the heater 130 disposed inside the chamber 110 to heat the crucible 120, the pulling unit 150 on which a seed crystal 152 is coupled to one end thereof, and a heat shield 155.

The chamber 110 provides a space in which predetermined processes for growing a single crystal ingot for a silicon wafer used for electronics parts such as a semiconductor, etc are performed.

The chamber 110 may include a first chamber 111 in which the crucible 120 is received and a second chamber 112 in which a single crystal ingot IG is grown on the first chamber 111. The first chamber 111 may be a growing chamber, and the second chamber 112 may be a pull chamber.

A radiant insulator 140 for preventing heat of the heater 130 from being radiated through a sidewall of the chamber 110 may be disposed on an inner wall of the chamber 110.

In the current embodiment, various factors such as a pressure condition within the rotating quartz crucible 120 may be adjusted to control an oxygen concentration when the silicon crystal is grown. For example, argon gas may be injected into the chamber 110 of the silicon single crystal grower to discharge the injected argon gas through a lower portion of the chamber 110, thereby controlling the oxygen concentration.

The crucible 120 is disposed inside the first chamber 111 to contain a silicon solution SM. Also, the crucible 120 may be formed of a quartz material. A crucible support 125 formed of graphite may be disposed outside the crucible 120 to support the crucible 120. The crucible support 125 may be fixedly disposed on a rotation shaft 127. The rotation shaft 127 may be rotated by a driving unit (not shown) to allow a solid-liquid interface to be maintain at an almost uniform height while it rotates and elevates the crucible 120.

The heater 130 may be disposed inside the first chamber 111 to heat the crucible 120. For example, the heater 130 may have a cylindrical shape surrounding the crucible support 125. The heater 130 melts a high-purity poly crystal lump accumulated within the crucible 120 to generate the silicon solution SM.

In the current embodiment, a czochralsk (CZ) method in which the single seed crystal 152 is immersed in the silicon solution SM, and then the single seed crystal slowly pulls up to grow crystals may be applied as a method for growing the silicon single crystal ingot IG.

According to the CZ method, a seed is immersed in a melt solution in which the poly silicon is melted, and then, the seed crystal is quickly grown to perform a necking process. Also, a single crystal is slowly grown in a diameter direction of the seed to perform a soldering process when the single crystal has a predetermined diameter. Thereafter, a body growing process is performed to grow a body having a predetermined length. Then, a tailing process in which the body is decreased in diameter and separated from the solution is performed to complete the growth of the single crystal ingot.

Thereafter, a cropping process for cutting a body portion of the single crystal ingot in which the crystals are grown may be performed, and then, an outer surface of a portion remaining in a rod shape may be ground to have a predetermined diameter.

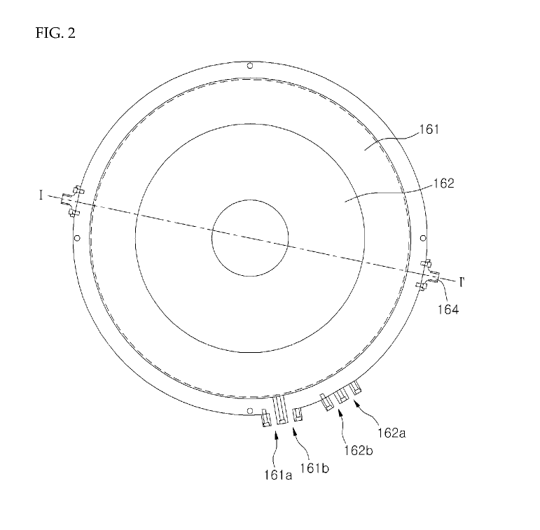

FIG. 2 is a plan view of a single crystal cooling apparatus according to an embodiment, and FIG. 3 is a plan view of a single crystal cooling apparatus according to another embodiment.

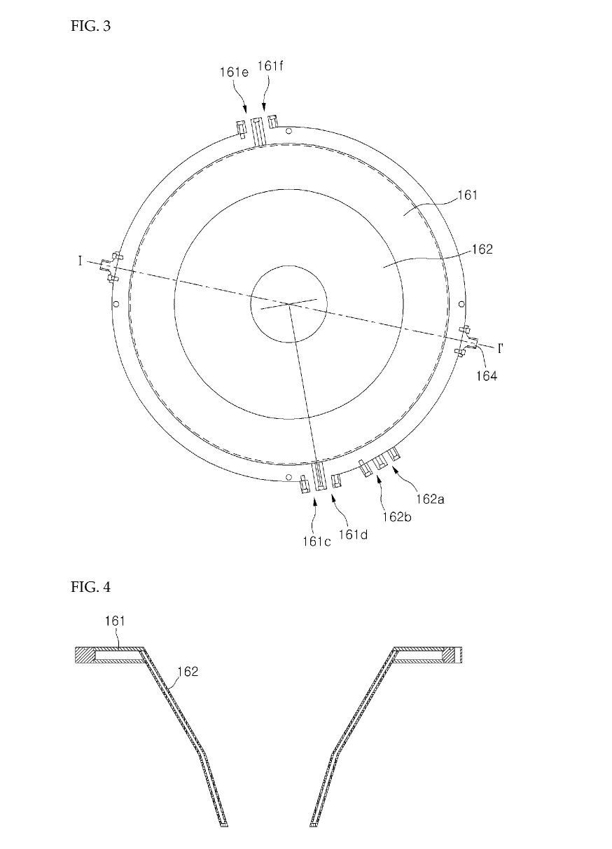

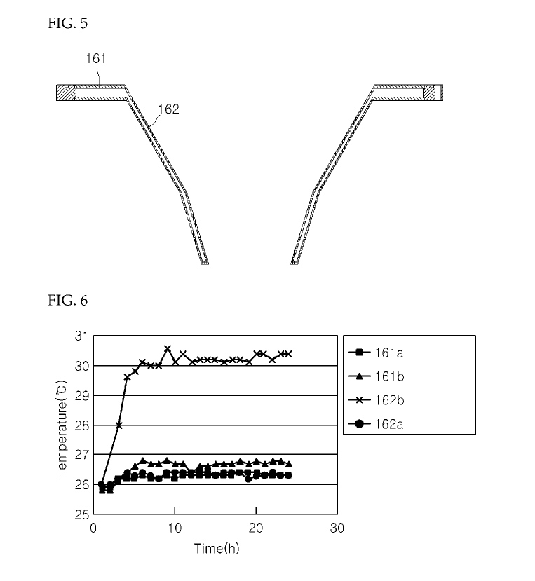

FIGS. 4 and 5 are sectional views taken along line I-I′ of the single crystal cooling apparatus illustrated in FIGS. 2 and 3.

According to the single crystal cooling apparatus, the cooling apparatus may be varied in position and configuration to allow the cooling apparatus and the melt solution surface to be maximally close to each other, thereby improving an ingot growth rate.

Also, according to an embodiment, an inner water circulation structure may be varied due to the configuration variation of the cooling apparatus to improve cooling performance and prevent the water from leaking.

For example, the single crystal cooling apparatus 160 according to an embodiment may have upper and lower portions having diameters different from each other. Also, the single crystal cooling apparatus 160 may approach the silicon solution SM within the first chamber 111 including the crucible 120 to improve a cooling rate of the single crystallized ingot IG.

For example, the single crystal cooling apparatus 160 may include an upper flange 161 having a circular shape and a lower flange 162 extending downward from the upper flange 161 and having a diameter less than that of the upper flange 161.

The single crystal cooling apparatus 160 may be disposed in a cone shape above the heat shield 155, but is not limited thereto. For example, the single crystal cooling apparatus 160 may be fixedly disposed inside the first chamber 111 by a coupling unit 164 such as a bolt or hook jaw.

The single crystal cooling apparatus 160 has an opened bottom end having a diameter greater than that of the ingot IG to allow the growing single crystal ingot IG to pass through.

The single crystal cooling apparatus 160 according to an embodiment may have a coolant circulation path in the lower flange 162 to cool the ingot.

For example, the single crystal cooling apparatus 160 according to an embodiment may include at least one or more first coolant injection holes 162a defined in one side of the lower flange 162 and at least one or more first coolant discharge hole 162b defined in the other side of the lower flange 162 to cool the ingot.

FIG. 4 is a sectional view of a single crystal cooling apparatus according to an embodiment.

In the current embodiment, each of the upper flange 161 and the lower flange 162 may have the coolant circulation path to reduce heat loads of the upper and lower flanges 161 and 162, but is not limited thereto. As shown in FIG. 5, the upper and lower flanges 161 and 162 may have a common coolant circulation path.

Although each of the upper and lower flanges 161 and 162 has the coolant circulation path in fallowing descriptions, the current embodiment is not limited thereto.

The single crystal cooling apparatus 160 according to an embodiment includes at least one or more second coolant injection holes 161a defined in one side of the upper flange 161 and at least one or more second coolant discharge hole 161b defined in the other side of the upper flange 161, at least one or more the first coolant injection holes 162a defined in the one side of the lower flange 162 and at least one or more the first coolant discharge hole 162b defined in the other side of the lower flange 162 to reduce the heat loads of the upper and lower flanges 161 and 162.

As shown in FIG. 2, when the second coolant injection hole 161a and the second coolant discharge hole 161b are adjacent to each other and the first coolant injection hole 162a and the first coolant discharge hole 162b are adjacent to each other, a coolant battier may be disposed between the injection holes and the discharge holes.

FIG. 3 is a plan view of a single crystal cooling apparatus according to another embodiment.

According to the current embodiment, a coolant injection hole and a coolant discharge hole of the upper flange 161 may be provided in plurality. Also, a coolant injection hole and a coolant discharge hole of the lower flange 162 may be provided in plurality.

For example, the upper flange 161 may include third and fourth coolant injection holes 161c and 161d and third and fourth coolant discharge holes 161e and 161f. The third coolant injection hole 161c may communicate with the third coolant discharge hole 161e, and the fourth coolant injection hole 161d may communicate with the fourth coolant discharge hole 161f, but are not limited thereto.

According to an embodiment, coolant barriers may be disposed between the third and fourth coolant injection holes 161c and 161d and between the third and fourth coolant discharge holes 161e and 161f, but are not limited thereto.

According to an embodiment, since the plurality of coolant injection holes and the plurality of coolant discharge holes are provided, the cooling efficiency of the single crystal cooling apparatus may be improved.

Furthermore, since the length and time required for circulating the coolant are reduced, the cooling efficiency may be improved. For example, as shown in FIG. 5, when the third and fourth coolant injection holes 161c and 161d are disposed in a direction opposite to that of the third and fourth coolant discharge holes 161e and 161f, e.g., when the third and fourth coolant injection holes 161c and 161d and the third and fourth coolant discharge holes 161e and 161f are disposed in directions opposite to each other with respect to a center of the upper flange 161, the length and time required for circulating the coolant may be reduced to improve the cooling efficiency.

FIG. 6 is a graph illustrating a coolant temperature variation when a single crystal cooling apparatus is applied according to an embodiment.

According to an embodiment, the coolant discharged after it is cooled in the upper and lower flanges 161 and 162 has a temperature of about 40° C. or less, i.e., a good temperature. For example, since the coolant discharged after it is cooled in the upper and lower flanges 161 and 162 has a temperature of about 31° C. or less, the ingot may be efficiently cooled.

As a result, according to the embodiment, a pulling speed may be improved to about 40% or more to very improve yield when compared to a related art.

In the single crystal cooling apparatus according to the embodiment and the single crystal grower including the same, the cooling apparatus may be varied in position and configuration to allow the cooling apparatus and the melt solution surface to be maximally close to each other, thereby improving the growth rate of the ingot.

Also, according to the embodiment, the inner water circulation structure may be varied due to the configuration variation of the cooling apparatus to improve the cooling performance and prevent the water from leaking.

In the single crystal cooling apparatus according to the embodiment and the single crystal grower including the same, the cooling apparatus may be varied in position and configuration to allow the cooling apparatus and the melt solution surface to be maximally close to each other, thereby improving the growth rate of the ingot.

The single crystal cooling apparatus according to the embodiment may include the upper flange having a circular shape and the lower flange extending downward from the upper flange and having a diameter less than that of the upper flange, but is not limited thereto.

Features, structures, and effects described in the above embodiments are incorporated into at least one embodiment of the present invention, but are not limited to only one embodiment. Moreover, features, structures, and effects exemplified in one embodiment can easily be combined and modified for another embodiment by those skilled in the art. Therefore, these combinations and modifications should be construed as falling within the scope of the present invention.

Although embodiments have been described with reference to illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims.

What is claimed is:

1. A single crystal cooling apparatus comprising:
an upper flange having a circular shape; and
a lower flange extending downward from the upper flange, the lower flange having a diameter less than that of the upper flange.

2. The single crystal cooling apparatus of claim 1, wherein the lower flange comprises a cone shape.

3. The single crystal cooling apparatus of claim 1, wherein the lower flange comprises an opened bottom end.

4. The single crystal cooling apparatus of claim 1, further comprising:
at least one first coolant injection hole defined in one side of the lower flange; and
at least one first coolant discharge hole defined in the other side of the lower flange.

5. The single crystal cooling apparatus of claim 4, further comprising:
at least one second coolant injection holes defined in one side of the upper flange; and
at least one second coolant discharge holes defined in the other side of the upper flange.

6. The single crystal cooling apparatus of claim 5, wherein the second coolant injection hole and the second coolant discharge hole are disposed in directions opposite to each other with respect to a center of the upper flange.

7. The single crystal cooling apparatus of claim 1, wherein each of the upper flange and the lower flange comprises a coolant circulation path.

8. The single crystal cooling apparatus of claim 1, wherein the upper flange and the lower flange comprises a common coolant circulation path.

9. The single crystal cooling apparatus of claim 1, wherein a coolant discharged after it is cooled in the upper flange and the lower flange has a temperature of about 40 or less.

10. A single crystal grower comprising:
a first chamber comprising a crucible;
a second chamber on the first chamber; and
a single crystal cooling apparatus in the first chamber.

11. The single crystal grower of claim 10, wherein the single crystal cooling apparatus comprises:
an upper flange having a circular shape,
a lower flange extending downward from the upper flange, the lower flange having a diameter less than that of the upper flange.
